(19) United States
(12) Patent Application Publication
(10) Pub. No.: US 2012/0280373 A1
(43) Pub. Date: Nov. 8, 2012

(54) ACTIVE ELECTRONICS ON STRENGTHENED GLASS WITH ALKALI BARRIER

(76) Inventors: Jiangwei Feng, Painted Post, NY (US); Mingqian He, Horseheads, NY (US); Jianfeng Li, Lake St. Louis, MO (US); Michael S. Pambianchi, Corning, NY (US); Michael Lesley Sorensen, Waverly, NY (US)

(21) Appl. No.: 13/462,146

(22) Filed: May 2, 2012

Related U.S. Application Data
(60) Provisional application No. 61/483,205, filed on May 6, 2011.

(51) Int. Cl. H01L 29/06; H01L 21/20

(52) U.S. Cl. 257/649; 257/632; 438/479; 257/E29.006; 257/E21.09

(57) ABSTRACT

Articles are described utilizing strengthened glass substrates, for example, ion-exchanged glass substrates, with oxide or nitride containing alkali barrier layers and with semiconductor devices which may be sensitive to alkali migration are described along with methods for making the articles.

This application claims the benefit of priority under 35 U.S.C. §119 of U.S. Provisional Application Ser. No. 61/483,205 filed on May 6, 2011 the content of which is relied upon and incorporated herein by reference in its entirety.

### BACKGROUND

1. Field

Embodiments relate generally to articles using strengthened glass as a substrate and more particularly to electronic devices using strengthened glass as substrates with alkali barrier layers comprising oxide or nitride.

2. Technical Background

Active electronic devices on glass are commonly fabricated in silicon technology, such as is currently practiced in thin-film transistor (TFT) arrays used in liquid crystal displays. However, current silicon technology requires high deposition temperatures (at least 500° C.) in order to achieve acceptable performance. These processing temperatures prevent the use of, for example, ion-exchanged glass substrates, since the surface strength and durability achieved by ion exchange is released through ion diffusion at temperatures in excess of 370° C. In addition, mobile alkali ion species, for example, Na and/or K in the ion-exchanged glass substrate can migrate into active electronic structures such as thin film transistors at these typical silicon processing temperatures, preventing proper operation of those active electronic structures.

Currently these types of devices need to use different forms of protection to prevent breakage of the backplane, including various forms of mounting hardware, bezel and frame structures, and other structures designed to prevent deformation or absorb shock.

It would be advantageous to create active electronic structures which can be deposited at lower temperatures on strengthened, for example, ion-exchanged glass substrates.

### SUMMARY

Fabrication of active electronic structures on ion-exchanged glass will enable strong, nearly unbreakable glass to be used as the electronic backplane in electronic devices such as liquid crystal displays. If the electronic backplanes were composed of ion-exchanged glass, much of this extra hardware could be eliminated, and new, frameless devices could be developed, with potential for greatly improved aesthetics, lighter weight, lower manufacturing costs, and/or improved product durability. If the active electronics on ion-exchanged glass are also composed of optically transparent materials, then this would enable transparent, all-glass electronic devices.

One possibility is to use strengthened glass, such as Gorilla® (registered Trademark of Corning Incorporated) Glass as the backplane substrate. Ion-exchanged Gorilla® Glass, however, is sodium and potassium rich on the surface and alkali metal is a disadvantage in semiconductor device operation and fabrication, for example, TFT manufacturing. Free alkali metal ions can contaminate typical silicon (Si) TFT devices, and alkali containing glass is to be avoided in the typical high temperature vacuum processing steps used to make Si TFTs. The use of alkali-free glass is acceptable for Si TFT fabrication, but alkali-free glass currently does not have the mechanical reliability of strengthened glass, for example, ion-exchanged glass. On the other hand, organic TFTs do not require high temperature processing. If a suitable alkali ion barrier existed, semiconductor devices, for example, organic TFTs could be fabricated onto a mechanically durable strengthened glass, for example, an ion-exchanged substrate.

Embodiments described herein may provide one or more of the following advantages: provide a practical way to fabricate TFTs and circuits on strengthened glass, for example, ion-exchanged glass substrates and promote the use of strengthened glass, for example, ion-exchanged glass as suitable substrates for display backplanes; allow the fabrication of electronic devices on strengthened glass, for example, ion-exchanged glasses without changing the superior compression strength of the glass; and/or provides an easy way to minimize the migration of ions on the ion-exchanged glasses into the electronic devices' active layer.

One embodiment is an article comprising a strengthened glass substrate having a first surface and a second surface and having a Vickers crack initiation threshold of at least 20 kgf; a barrier layer having a first surface and a second surface, wherein the first surface of the barrier layer is adjacent to the second surface of the strengthened glass substrate, and wherein the barrier layer comprises an oxide or a nitride; and a device comprising a semiconductor film adjacent to the second surface of the barrier layer.

Another embodiment is a method comprising providing a strengthened glass substrate having a first surface and a second surface and having a Vickers crack initiation threshold of at least 20 kgf, applying a barrier layer having a first surface and a second surface, wherein the first surface of the barrier layer is adjacent to the second surface of the strengthened glass substrate, and wherein the barrier layer comprises an oxide or a nitride, and forming a device comprising a semiconductor film adjacent to the second surface of the barrier layer.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 is an illustration of an article according to one embodiment.

FIG. 2 is an illustration of an article according to one embodiment.

FIG. 3 is a side view illustration showing a bottom-gate top-contact (BG-TC) TFT device.

FIG. 4 is a side view illustration showing a bottom-gate bottom-contact (BG-BC) TFT device.

FIG. 5 is a side view illustration showing a top-gate bottom-contact (TG-BC) TFT device.

FIG. 6 is a side view illustration showing a top-gate top-contact (TG-TC) TFT device.

FIG. 7 shows an exemplary TFT structure.

FIG. 8 shows an exemplary TFT structure.

FIGS. 9-11 are Secondary Ion Mass Spectroscopy (SIMS) measurement profiles of exemplary articles.

FIG. 12 is a graph showing device performance of exemplary articles.

FIG. 13 is a graph showing ring on ring load failures of exemplary ion-exchanged glass substrates at various thicknesses.

### DETAILED DESCRIPTION

Reference will now be made in detail to various embodiments.

As used herein, the term “substrate” can be used to describe either a substrate or a superstrate depending on the configuration of the device. For example, the substrate is a superstrate, if when assembled into, for example, a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module. Photovoltaic device can describe either a cell, a module, or both.

As used herein, the term “adjacent” can be defined as being in close proximity. Adjacent structures may or may not be in physical contact with each other. Adjacent structures can have other layers and/or structures disposed between them.

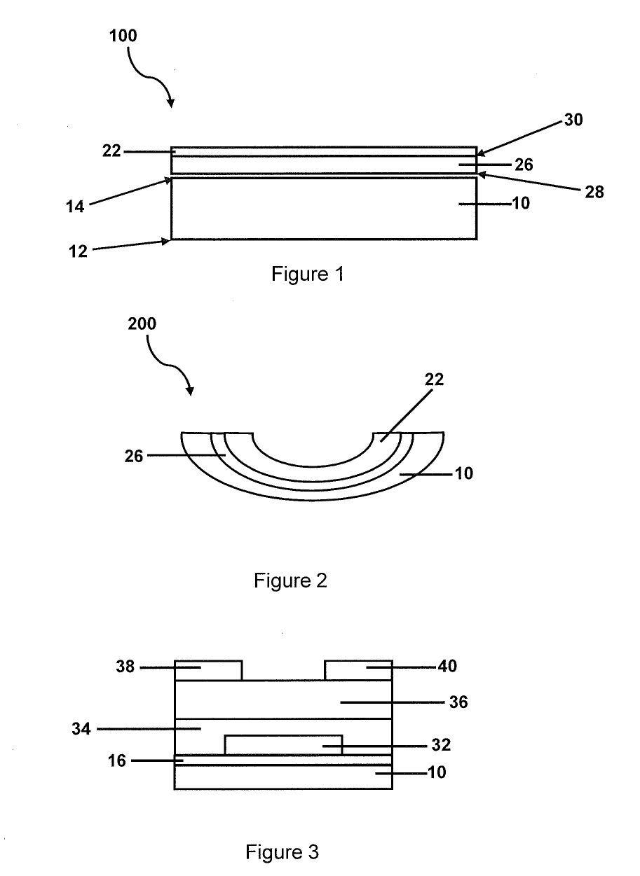

One embodiment, as shown in FIG. 1 is an article 100 comprising a strengthened glass substrate 10 having a first surface 12 and a second surface 14 and having a Vickers crack initiation threshold of at least 20 kgf; a barrier layer 26 having a first surface 28 and a second surface 30, wherein the first surface 28 of the barrier layer 26 is adjacent to the second surface 14 of the strengthened glass substrate 10, and wherein the barrier layer comprises an oxide or a nitride; and a device 22 comprising a semiconductor film adjacent to the second surface 30 of the barrier layer 26.

In one embodiment, the strengthened glass substrate is in the form of a glass sheet. The strengthened glass substrate can be an ion-exchanged glass. The strengthened glass substrate can be planar or non-planar, for example, the strengthened glass substrate can be curved with a single or variable radius. As shown in FIG. 2, the barrier layer 26 can be disposed to the concave surface of the curved strengthened glass substrate 10. A device 22 comprising a semiconductor film can be disposed on the barrier layer 26. An alternative example not shown is that the barrier layer can also be bonded to the convex surface of the curved strengthened glass substrate.

According to some embodiments, the strengthened glass substrate has a thickness of 4.0 mm or less, for example, 3.5 mm or less, for example, 3.2 mm or less, for example, 3.0 mm or less, for example, 2.5 mm or less, for example, 2.0 mm or less, for example, 1.9 mm or less, for example, 1.8 mm or less, for example, 1.5 mm or less, for example, 1.1 mm or less, for example, 0.5 mm to 2.0 mm, for example, 0.5 mm to 1.1 mm, for example, 0.7 mm to 1.1 mm. Although these are exemplary thicknesses, the strengthened glass substrate can have a thickness of any numerical value including decimal places in the range of from 0.1 mm up to and including 4.0 mm.

Glasses designed for use in applications such as in consumer electronics and other areas where high levels of damage resistance are desirable are frequently strengthened by thermal means (e.g., thermal tempering) or chemical means. Ion-exchange is widely used to chemically strengthen glass articles for such applications. In this process, a glass article containing a first metal ion (e.g., alkali cations in Li₂O, Na₂O, etc.) is at least partially immersed in or otherwise contacted with an ion-exchange bath or medium containing a second metal ion that is either larger or smaller than the first metal ion that is present in the glass. The first metal ions diffuse from the glass surface into the ion-exchange bath/medium while the second metal ions from the ion-exchange bath/medium replace the first metal ions in the glass to a depth of layer below the surface of the glass. The substitution of larger ions for smaller ions in the glass creates a compressive stress at the glass surface, whereas substitution of smaller ions for larger ions in the glass typically creates a tensile stress at the surface of the glass. In some embodiments, the first metal ion and second metal ion are monovalent alkali metal ions. However, other monovalent metal ions such as Ag⁺, Tl⁺, Cu⁺, and the like may also be used in the ion-exchange process.

In one embodiment, the strengthened glass substrate is an aluminoborosilicate, an alkalialuminoborosilicate, an aluminosilicate, or an alkalialuminosilicate. In one embodiment, the strengthened glass substrate is an ion-exchanged glass substrate.

In one embodiment, the strengthened glass substrate comprises a strengthened glass wherein the glass is ion-exchanged to a depth of layer of at least 20 μm from a surface of the glass.

In one embodiment, the strengthened glass substrates described herein, when chemically strengthened by ion-exchange, exhibit a Vickers initiation cracking threshold of at least about 5 kgf (kilogram force), in some embodiments, at least about 10 kgf, in some embodiments and, in other embodiments, at least about 20 kgf, for example, at least about 30 kgf. FIG. 13 is a graph showing ring on ring load failures of exemplary ion-exchanged glass substrates, for example, Gorilla® glass at various thicknesses.

In one embodiment, a functional layer is disposed on the first surface of the strengthened glass substrate. The functional layer can be selected from an anti-glare layer, an anti-smudge layer, a self-cleaning layer, an anti-reflection layer, an anti-fingerprint layer, an optically scattering layer, anti-splintering, and combinations thereof.

In one embodiment, the strengthened glass is optically transparent. In another embodiment, the barrier layer is optically transparent. In another embodiment, the device is optically transparent. In another embodiment, the functional layer is optically transparent. This would enable transparent, all-glass electronic devices.

Another embodiment is a method comprising providing a strengthened glass substrate having a first surface and a second surface and having a Vickers crack initiation threshold of at least 20 kgf; applying a barrier layer having a first surface and a second surface, wherein the first surface of the barrier layer is adjacent to the second surface of the strengthened glass substrate, and wherein the barrier layer comprises an oxide or a nitride; and forming a device comprising a semiconductor film adjacent to the second surface of the barrier layer.

In one embodiment, the barrier layer comprises the oxide having a formula of MₓO_{y}, wherein x is an integer from 1 to 6, y is an integer from 1 to 30 such that MₓO_{y} is a charge neutral species, and M is a metal or a non-metal. In one embodiment the barrier layer is Aluminum Oxide (Al₂O₃).

In another embodiment, the barrier layer comprises the nitride having a formula of MₓN_{y}, wherein x is an integer from 1 to 6, y is an integer from 1 to 30 such that MₓN_{y} is a charge neutral species, and M is a metal or a non-metal. In one embodiment, the barrier layer comprises Silicon Nitride (Si₃N₄).

After the barrier layer is applied to the strengthened glass substrate, devices comprising a semiconductor film can be fabricated on the second surface of the barrier layer. In one embodiment, the device is selected from a photovoltaic device, a thin-film transistor, a diode, and a display device.

For example, an organic TFT device can include: an ion-exchanged glass substrate including the barrier layer. On the barrier layer a gate electrode, a dielectric layer, a drain electrode, a source electrode, and an organic semiconducting channel layer can be formed. These layers can be stacked in different sequences to form a laterally or vertically configured transistor device. The organic semiconducting channel layer includes semiconducting small molecules, oligomers and/or polymers. The dielectric layer can be composed of any organic or inorganic material that is able to be applied as a film at or below 200° C. In this way, a mechanically durable backplane is produced.

FIGS. 3-8 illustrate embodiments of articles comprising TFT devices. As used herein, the term “bottom-gate top-contact transistor” refers to a TFT device comprising an exemplary structure as shown in FIG. 3. A gate electrode 32 is deposited on a barrier layer 16 on a strengthened glass substrate, or ion-exchanged glass substrate 10 (according to any of the previously described embodiments) followed by a dielectric layer 34 and then a semiconducting layer 36. Drain and source electrodes 38 and 40, respectively, are further deposited on top of the semiconducting layer 36.

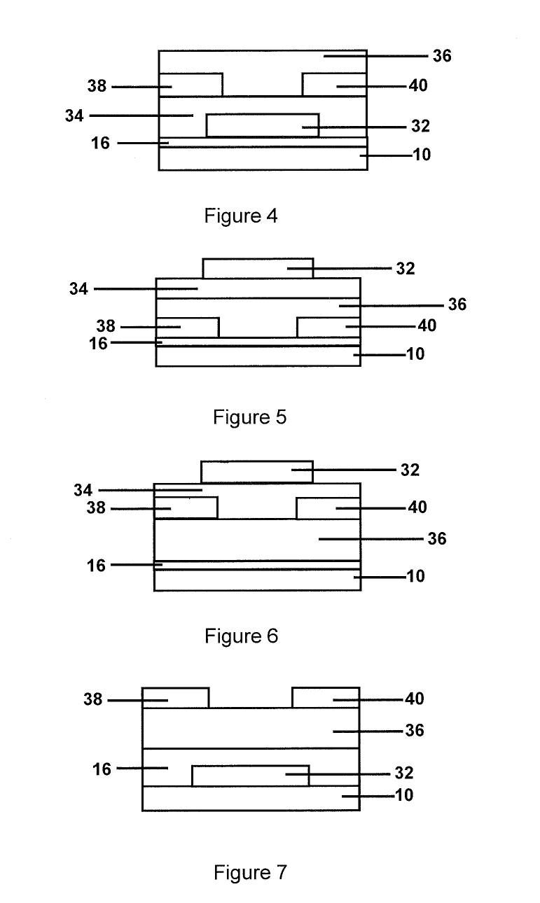

The term “bottom-gate bottom-contact transistor” refers to a TFT device comprising an exemplary structure as shown in FIG. 4. A gate electrode 32 is deposited on a barrier layer 16 on a strengthened glass substrate, or ion-exchanged glass substrate 10 followed by a dielectric layer 34 and then drain and source electrodes 38 and 40, respectively. A semiconducting layer 36 is further deposited on top of these underlying layers.

The term “top-gate bottom-contact transistor” refers to a TFT device comprising an exemplary structure as shown in FIG. 5. Drain and source electrodes 38 and 40, respectively are deposited on a barrier layer 16 on a strengthened glass or ion-exchanged glass substrate 10 (according to any of the previously described embodiments). A semiconducting layer 36 is then deposited on top, followed by a dielectric layer 34 and then a gate electrode 32.

The term “top-gate top-contact transistor” refers to a TFT device comprising an exemplary structure as shown in FIG. 6. A semiconducting layer 36 is deposited on a barrier layer 16 strengthened glass substrate, or ion-exchanged glass substrate 10 followed by drain and source electrodes 38 and 40, respectively. A dielectric layer 34 is further deposited on top, followed by a gate electrode 32.

FIG. 7 shows an exemplary TFT structure. A semiconducting layer 36 is deposited on a barrier layer 16 on a strengthened glass substrate, or ion-exchanged glass substrate 10. A gate electrode 32 is disposed between the strengthened substrate and the barrier layer, followed by drain and source electrodes 38 and 40, respectively on the semiconducting layer.

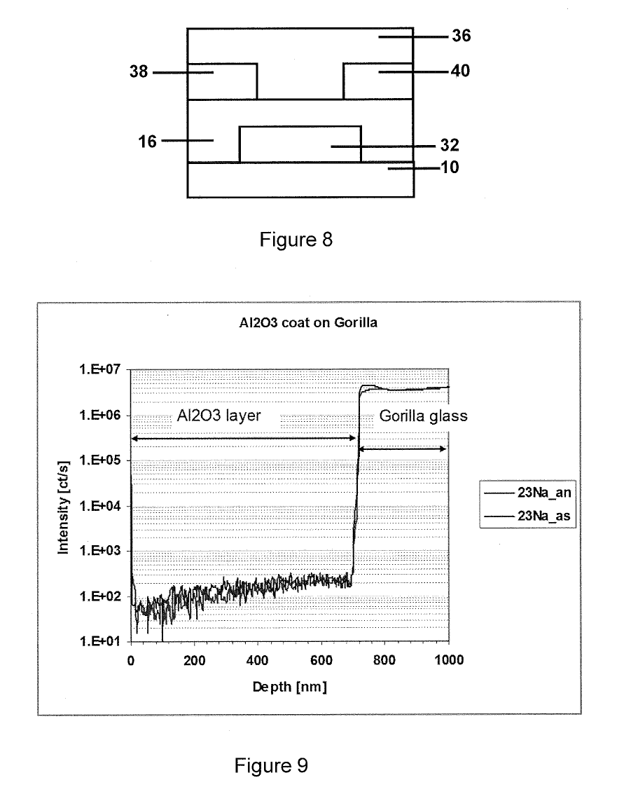

FIG. 8 shows an exemplary TFT structure. A semiconducting layer 36 is deposited on a barrier layer 16 on a strengthened glass substrate, or ion-exchanged glass substrate 10. A gate electrode 32 is disposed between the strengthened substrate and the barrier layer. Drain and source electrodes 38 and 40, respectively are disposed on the barrier layer and under the semiconducting layer.

### EXAMPLES

The present invention describes active electronic structures fabricated on strengthened glass substrates, for example, ion-exchanged glass substrates and methods for fabricating the structures. The structures can comprise a glass substrate which has undergone ion-exchange surface treatment.

A barrier layer deposited on top of the ion-exchanged glass substrate, having an oxide ceramic composition selected from Al₂O₃, Si₃N₄, SiO₂ and other metal oxides like Cr, Zr, Ta, and Hf or their non-conductive nitride compound, which forms a barrier layer to prevent migration of alkali atoms out of the ion-exchanged glass substrate. The coated glass should have the same or even better mechanical strength when compared with non-coated ion-exchanged glass. An experiment conducted by the inventors indicated that the coated glass samples showed the same strength at room temperature.

TABLE 1
Before 200 C. annealing

| sample #1 | CS | DOL | sample #2 | CS | DOL |
|---|---|---|---|---|---|
| Non coated | 739 | 42 | Non | 739 | 42 |
| Coated | 737 | 41 | coated | | |
| | | | Coated | 739 | 40 |

after 200 C. annealing

| sample #1 | CS | DOL |
|---|---|---|
| Non coated | 744 | 43 |
| Coated | 745 | 41 |

The glass sample showed the same strength even after 2 hours of annealing at 200° C. as shown in Table 1. Here the CS is compress stress; DOL indicates depth of layer of ion exchanged ions in the glass after ion-exchange (IOX) process, such as K ion depth in the glass.

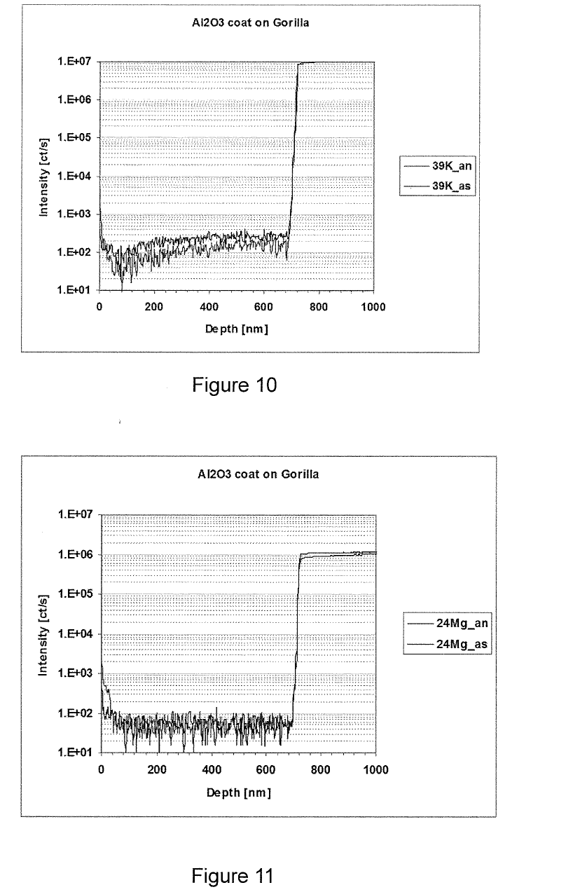

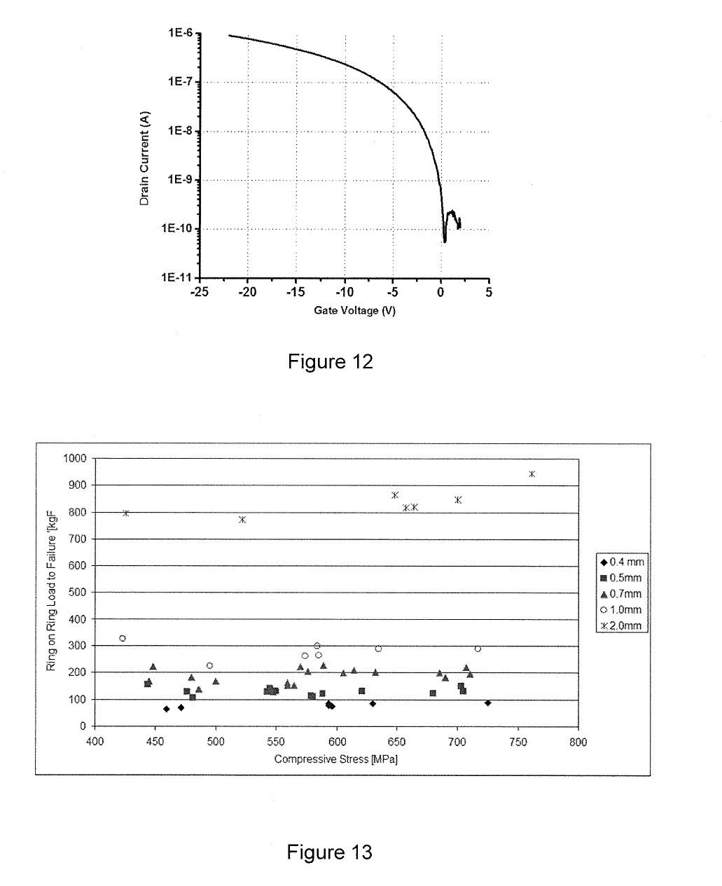

In order to decide if ions such as Na, K or other metals would diffuse into coated layer, Secondary Ion Mass Spectroscopy (SIMS) measurements were conducted. The profiles are shown in FIGS. 9-11.

Experiments indicated that no significant amount of Na or K ions diffuse into the Al₂O₃ coating (barrier layer) after annealing at 200° C. for 2 hours, as shown by the steep interface between Al₂O₃ and Gorilla® (registered Trademark of Corning Incorporated) Glass. Note that the slightly higher concentration of Na, K and Mg on top of Al₂O₃ is due to surface contamination. The inventors used this slightly contaminated barrier layer on a Gorilla® glass substrate to then build an OTFT device on the barrier layer.

An exemplary method of making an article according to the present invention is as follows:
Strengthened glass substrates with a barrier layer were washed using a detergent followed by DI-water, then by toluene, then by acetone, and then 2-propanol. The washed strengthened glass substrates with a barrier layer were then dried with a nitrogen (N₂) gun.
The dried strengthened glass substrates with the barrier layer were then place in a UV-Ozone cleaner for 10 mins. A thermal evaporator was used to deposit a layer of 80 nm Al on the barrier layer as the common gate electrode at a rate of 4 Å/s.
A solution of 2 ml of 5 wt % PVP-co-PMMA with hexamethoxymethylmelamine (weight ratio of PVP-co-PMMA:hexamethoxymethylmelamine=10:1) was mixed in PGMEA solvent.
The Al film coated glass substrates with the barrier layer were placed in a UV-ozone cleaner for 10 mins. Afterwards, the cleaned substrates were placed on a spin-coater in air and PVP-co-PMMA solution was dropped on the Al film on the barrier layer coated glass substrates, then spin cast at 1000 rpm for 60 sec;
The PVP-co-PMMA coated Al film on the barrier layer coated glass substrates were placed on hotplate at 120° C. for 2 mins to remove solvent, and then cured under UV light to make the dielectric film cross-linked;
A 3 mg/ml DC17FT4 polymer solution in decalin was prepared by heating at 160° C. for 2 hr, cooling down to RT, and then filtering through 0.45 μm filter.
The DC17FT4 OSC solution was spin casted onto the dielectric film at 1000 rpm for 60 sec, then annealed at 150° C. on in a N₂ oven for about 30 mins.
Au source and drain electrodes were then deposited at 2.5 Å/s for a 50 nm thickness.
Devices were tested in air by using Au wire probes.

The inventors believe that Silicon Nitride should give the same performance since several references had used this compound as barrier layer to prevent Na migrations.

Ion-exchanged glass is mechanically strong and durable when compared with non ion-exchanged glasses. However, due to rich Na and K ions, the ion-exchanged glass can not be used directly for fabrication of active electronic backplane. In this invention, we have successfully solved this problem by fabricating OTFT devices on the Al₂O₃ coated ion-exchanged glass. Here are the key summaries:

1. Deposit transparent Al₂O₃ or Si₃N₄ at low temperature <300 C on ion exchanged glass. Low temperature deposit is advantageous to preserve ion-exchanged glass strength.
2. Fabricate OTFT or oxide TFT device on top of the ion exchanged glass at low temperature. Low temperature fabrication process can prevent ion migration from glass to barrier layer at same time to maintain glass mechanical strength.

The present invention may improve the durability of electronic devices which employ glass substrates, enable durable all-glass electronic devices with no bezel or framing hardware, reduce manufacturing cost through the elimination of unneeded mounting hardware and shock absorption, and/or lower device manufacturing cost through use of lower processing temperatures and potentially also through use of solution-based processing (i.e., printing).

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. An article comprising:
a strengthened glass substrate having a first surface and a second surface and having a Vickers crack initiation threshold of at least 20 kgf;
a barrier layer having a first surface and a second surface, wherein the first surface of the barrier layer is adjacent to the second surface of the strengthened glass substrate, and wherein the barrier layer comprises an oxide or a nitride; and
a device comprising a semiconductor film adjacent to the second surface of the barrier layer.

2. The article according to claim 1, wherein the barrier layer comprises the oxide having a formula of MₓO_{y}, wherein x is an integer from 1 to 6, y is an integer from 1 to 30 such that MₓO_{y} is a charge neutral species, and M is a metal or a non-metal.

3. The article according to claim 2, wherein the barrier layer is Aluminum Oxide.

4. The article according to claim 1, wherein the barrier layer comprises the nitride having a formula of MₓN_{y}, wherein x is an integer from 1 to 6, y is an integer from 1 to 30 such that MₓN_{y} is a charge neutral species, and M is a metal or a non-metal.

5. The article according to claim 4, wherein the barrier layer comprises Silicon Nitride.

6. The article according to claim 1, wherein the strengthened glass substrate is an ion-exchanged glass.

7. The article according to claim 1, further comprising a functional layer disposed on the first surface of the strengthened glass substrate.

8. The article according to claim 1, wherein the functional layer is selected from an anti-glare layer, an anti-smudge layer, a self-cleaning layer, an anti-reflection layer, an anti-fingerprint layer, an optically scattering layer, anti-splintering, and combinations thereof.

9. The article according to claim 1, wherein the strengthened glass substrate is curved.

10. The article according to claim 1, wherein the device is selected from a photovoltaic device, a thin-film transistor, a diode, and a display device.

11. The article according to claim 1, wherein the glass substrate is a glass sheet.

12. The article according to claim 1, wherein the barrier layer is disposed on the glass substrate.

13. The article according to claim 1, wherein the glass substrate is optically transparent.

14. The article according to claim 1, wherein the barrier layer is optically transparent.

15. The article according to claim 1, wherein the device is optically transparent.

16. The article according to claim 1, wherein the glass substrate, the barrier layer, and the device are optically transparent.

17. A method comprising:
providing a strengthened glass substrate having a first surface and a second surface and having a Vickers crack initiation threshold of at least 20 kgf;
applying a barrier layer having a first surface and a second surface, wherein the first surface of the barrier layer is adjacent to the second surface of the strengthened glass substrate, and wherein the barrier layer comprises an oxide or a nitride; and
forming a device comprising a semiconductor film adjacent to the second surface of the barrier layer.

18. The method according to claim 17, wherein the glass substrate is optically transparent.

19. The method according to claim 17, wherein the barrier layer is optically transparent.

20. The method according to claim 17, wherein the device is optically transparent.
